(19) United States
(12) Patent Application Publication
(10) Pub. No.: US 2009/0027328 A1
(43) Pub. Date: Jan. 29, 2009

(54) ACTIVE MATRIX DEVICES

(75) Inventors: Mark Thomas Johnson, Eindhoven (NL); Eliav Itzhak Haskal, Eindhoven (NL); Alan George Knapp, Pound Hill (GB)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/573,898

(22) PCT Filed: Jul. 27, 2005
(86) PCT No.: PCT/IB2005/052523

§ 371 Date: Feb. 19, 2007

(30) Foreign Application Priority Data
Aug. 23, 2004 (EP) 04104040.3

(51) Int. Cl. G02F 1/167; G09G 3/20; H01L 21/28

(52) U.S. Cl. 345/107; 345/55; 438/29; 257/E21.158

(57) ABSTRACT

An active matrix device has an array of rows and columns of pixels over a common substrate. Each pixel has a row conductor (12), a column conductor (10) and first and second in-plane electrode patterns (36,40). A first insulator portion (30) is disposed between the row conductor (12) and the first electrode pattern (32) or between the column conductor portion (10) and the second electrode pattern (40). The insulator portion (30) and the surrounding electrode pattern (32 or 40) and conductor portion (12 or 10) define a Metal-Insulator-Metal diode device. The invention provides a MIM-diode based active matrix inplane switching active matrix device in which the pixel layout is defined on a single substrate. The device of the invention is compatible with low cost manufacturing processes, such as roll-to-roll manufacturing.

This invention relates to active matrix devices, in particular electrophoretic active matrix display devices.

Electrophoretic display devices use the movement of particles within an electric field to provide a selective light transmission or light blocking function. The particles may themselves be coloured, and the electric field can be used to bring the coloured particles to the surface of the device so that they are seen. Alternatively, an underlying layer may have coloured regions, and the particles may then block the passage of light to the underlying colour or else permit this passage of light. The particles are then typically black or white.

It has been recognised that electrophoretic display devices enable low power consumption and thin display devices to be formed. They may also be made from plastics materials, and there is also the possibility of low cost reel-to reel processing in the manufacture of such displays.

An electrophoretic display typically comprises a lower electrode layer, a display medium layer, and an upper electrode layer. Biasing voltages are applied selectively to electrodes in the upper and/or lower electrode layers to control the state of the portion(s) of the display medium associated with the electrodes being biased.

In the simplest form, a passive matrix addressing scheme is used. FIG. 1 shows a known passive matrix display layout for generating perpendicular electric fields between the top column electrodes 10 and the bottom row electrodes 12. The electrodes are generally situated on two separate substrates.

The passive matrix electrophoretic display comprises an array of electrophoretic cells arranged in rows and columns and sandwiched between the top and bottom electrode layers. The column electrodes 10 are transparent.

Cross bias is a problem in the design of passive matrix displays. Cross bias refers to the bias voltages applied to electrodes that are associated with display cells that are not in the scanning row (the row being updated with display data). For example, to change the state of cells in a scanning row in a typical display, bias voltages might be applied to column electrodes in the top electrode layer for those cells to be changed, or to hold cells in their initial state. Such column electrodes are associated with all of the display cells in their column, including the many cells not located in the scanning row.

A further problem associated with the use of passive matrix addressing is that the driving signals must be introduced to the display sequentially, typically one line at a time, along the (orthogonal) selection rows and data columns. Once the line is no longer being addressed, the electrical field is reduced to a level whereby the particles will not move. As a consequence, the particles only move whilst a line is addressed, and it will take a long time to complete addressing the display (in general, the response speed of the pixel times the number of rows in the display). As the display operates using the physical movement of particles, there is a limit to the speed at which a pixel can be addressed.

In order to speed up the addressing and to overcome the cross bias problem, it is known to use active matrix addressing, which ensures that the driving voltage is maintained during the time that other lines of the display are being selected, and also provides electrical isolation of pixels from the signal lines when not being addressed.

In an active matrix display, switching elements such as diodes or transistors are used, either alone or in conjunction with other elements, to control pixel electrodes associated with the display cell or cells associated with an individual pixel.

In one typical active matrix display configuration, for example, a common potential (e.g., ground potential) may be applied to a common electrode in the top layer and pixel electrodes located in the bottom layer are controlled by associated switching elements to either apply a biasing voltage to the pixel electrode or to isolate the pixel electrode to prevent an electric field from being generated that would cause the associated display cell(s) to change state.

Electrophoretic display devices can use the movement of particles in a number of ways. In a system generating transverse electric fields, as shown in FIG. 1, the particles are controlled to move selectively up and down the display material layer. When the particles are at the top, they are visible, and when they are at the bottom, then they are not visible, and the medium supporting the particles is then visible. The particles may be white, and the supporting medium may be red, green or blue.

Another type of electrophoretic display device uses so-called “in plane switching”. This type of device uses movement of the particles selectively laterally in the display material layer. When the particles are moved towards lateral electrodes, an opening appears between the particles, through which an underlying surface can be seen. When the particles are randomly dispersed, they block the passage of light to the underlying surface and the particle colour is seen. The particles may be coloured and the underlying surface black or white, or else the particles can be black or white, and the underlying surface coloured.

An advantage of in-plane switching is that the device can be adapted for transmissive operation, or transflective operation. In particular, the movement of the particles creates a passageway for light, so that both reflective and transmissive operation can be implemented through the material.

This invention relates specifically to the use of in-plane switching in active matrix electrophoretic displays.

A problem with the known in-plane switching active matrix devices is the complexity of the manufacturing process, and the incompatibility of such processes with roll to roll fabrication techniques. An object of the invention is to provide an active matrix device which can be made by a simplified process, and to provide the process itself.

According to the invention, there is provided an active matrix device, comprising an array of rows and columns of pixels disposed over a substrate, each pixel comprising, over a common substrate:

a portion of a row conductor, the row conductor extending past all the pixels of a row;

a first electrode pattern including a first in-plane electrode terminal, associated with the row conductor portion,

a portion of a column conductor, the column conductor extending past all the pixels of a column;

a second electrode pattern including a second in-plane electrode terminal, associated with the column conductor portion;

a first insulator portion disposed between the row conductor portion and the first electrode pattern or between the column conductor portion and the second electrode pattern, the insulator portion and the surrounding electrode pattern and conductor portion defining a Metal-Insulator-Metal diode device.

The invention provides a MIM-diode based active matrix in-plane switching active matrix device in which the pixel layout is defined on a single substrate. The device of the invention is compatible with low cost manufacturing processes, such as roll-to-roll manufacturing.

The first electrode pattern can include a portion which crosses the row conductor portion, the first insulator portion being provided between the portion of the first electrode pattern and the row conductor portion. This defines the MIM diode between the row conductor and an in-plane terminal. Each pixel may then further comprise a second insulator portion between the overlap of the row conductor portion and the column conductor portion.

The first in-plane pixel electrode terminal may comprise a comb pattern and the second in-plane pixel electrode terminal then also comprises a comb pattern interleaved with the comb pattern of the first in-plane pixel electrode terminal.

The first in-plane pixel electrode terminal may instead comprise an electrode block which extends parallel to the row conductor portion and the second in-plane pixel electrode terminal then comprises an electrode block which is spaced from the first in-plane pixel electrode block terminal in the column direction.

Each pixel preferably further comprises a second insulator portion between the cross over of the row and column conductors. The first electrode patterns, the column conductors and the second electrode patterns may all be formed from a common metal layer.

If the effective insulator provided between electrodes consists only of the second insulator then the second insulator will have different electrical properties, specifically a higher breakdown voltage, achieved by using a different insulator material or a thicker layer of the same material. In some cases the effective insulation provided between electrodes will comprise a combined layer of the first and second insulator layers in which the composition and thickness of the second layer are adjusted to give the required electrical properties, specifically a higher breakdown voltage, for the combination of the two layers.

This common metal layer may be disposed over the substrate, the first and second insulator portions may be disposed over the common metal layer and the row conductor may be disposed over the first and second insulator portions. In this arrangement, a single patterned layer defines both of the electrode patterns, so that there is only one patterning step involving high resolution details.

In another arrangement, the first in-plane pixel electrode terminals, the row conductors and the second in-plane pixel electrode terminals are all formed from a common metal layer. The end terminals of the first electrode patterns and the column electrodes are formed from a different layer, with the end terminals connecting to the first in-plane pixel electrode terminals and the column electrodes connecting to the second-in plane electrode terminals. The common metal layer is then disposed over the substrate, the first and second insulator portions are disposed over the common metal layer, and the column conductors and the end terminals of the first electrode patterns are disposed over the first and second insulator portions.

In a further embodiment, with the first in-plane electrode terminals and the second in-plane electrode terminals formed from the same layer, each pixel further comprises a capacitor terminal.

This arrangement incorporates a storage capacitor into the MIM based active matrix, and defined as two capacitances in series between the two in-plane electrode terminals, and connected together by the capacitor terminal.

The capacitor terminal can be formed from the material of the row conductors, and in this case, the second insulator portion can be arranged to extend over the row conductors and over the capacitor terminals, with the common metal layer of the in-plane electrode terminals formed over the second insulator portion.

In this arrangement, the second insulator portion is preferably substantially continuous and is provided with an opening in which the insulator portion of the Metal-Insulator-Metal diode is formed, the common metal layer being formed over the insulator portion of the Metal-Insulator-Metal diode device and the second insulator portion.

The Metal-Insulator-Metal diode device may comprise a TaOx diode. The Metal-Insulator-Metal diode device may also comprise a non-stoichiometric hydrogenated SiN layer.

In all embodiments, the Metal-Insulator-Metal diode device may comprise a plurality of diodes in series. For example, the first electrode pattern may include a second isolated end terminal and the row conductor material may define an isolated additional terminal, the Metal-Insulator-Metal diode device comprising three diodes in series.

The invention also provides a method of manufacturing an active matrix device, comprising an array of rows and columns of pixels disposed over a substrate, the method comprising forming, over a common substrate:

a row conductor array;

an array of first electrode patterns each including a first in-plane electrode terminal;

a column conductor array;

an array of second electrode patterns each including a second in-plane electrode terminal, wherein the method comprises forming a first insulator layer having portions between the row conductor array and the first electrode pattern array or between the column conductor array and the second electrode pattern array, the insulator portions and the surrounding electrode pattern and conductor portion defining a Metal-Insulator-Metal diode device.

In an embodiment the method further comprises forming a second insulator portion between the overlap of the row conductors and the column conductors.

In another embodiment the first in-plane electrode terminals and the second in-plane electrode terminals are formed from a common metal layer.

In another embodiment the column conductors and the second in-plane electrode terminals are formed from a common metal layer. In a variation on the embodiment the common metal layer is disposed over the substrate, the first insulator layer is disposed over at least a part of the common metal layer and the row conductors are disposed over the first insulator layer.

In another embodiment the first in-plane pixel electrode terminals, the row conductors and the second in-plane pixel electrode terminals are all formed from a common metal layer. In a variation on the embodiment the first in-plane electrode terminals are defined as substantially parallel comb lines, and wherein the first electrode pattern further comprises substantially perpendicular connecting portions connecting the parallel comb lines, and deposited in a separate step. In a further variation the second in-plane electrode terminals comprise comb lines substantially parallel to the comb lines of the first in-plane electrode terminals, and wherein the column conductors connect the parallel comb lines of the second in-plane electrode terminal and are formed from the same layer as the connecting portions of the first electrode pattern. In a yet further variation the common metal layer is disposed over the substrate, the first insulator layer is disposed over at least a portion of the common metal layer, and the connecting portions and column conductors are disposed over the first insulator layer.

In another embodiment the common metal layer is formed from an array of substantially parallel lines. In a variation on the embodiment the column conductors and the connecting portions are formed from a further metal layer comprising an array of parallel lines. In a further variation the lines of the further metal layer are formed substantially perpendicular to the parallel lines of the common metal layer.

In another embodiment the first in-plane electrode terminals and the second in-plane electrode terminals are formed from the same layer, and wherein the method further comprises forming an array of capacitor terminals.

In another embodiment the method further comprises forming a second insulator layer comprising portions between the overlap of the row conductors and the column conductors, and wherein the second insulator layer extends over the row conductors and over the capacitor terminals, and wherein the common metal layer is formed over the second insulator layer. In a variation on the embodiment the first insulator layer is formed as a first oxidized layer of the metal layer forming one terminal of the Metal-Insulator-Metal diode device. In a further variation the second insulator layer over the capacitor terminal comprises a second oxidized layer of the metal layer forming the capacitor terminal.

In another embodiment the method comprises a roll to roll manufacturing process. Furthermore, each patterned conductor layer can be arranged as an array of parallel lines, and this simplifies manufacture in such a roll to roll process.

The mere fact that certain measures are mentioned in different claims or different embodiments does not indicate that a combination of these measures cannot be used to advantage.

Examples of the invention will now be described in detail with reference to the accompanying drawings, in which:

FIG. 1 shows a known passive matrix display layout;

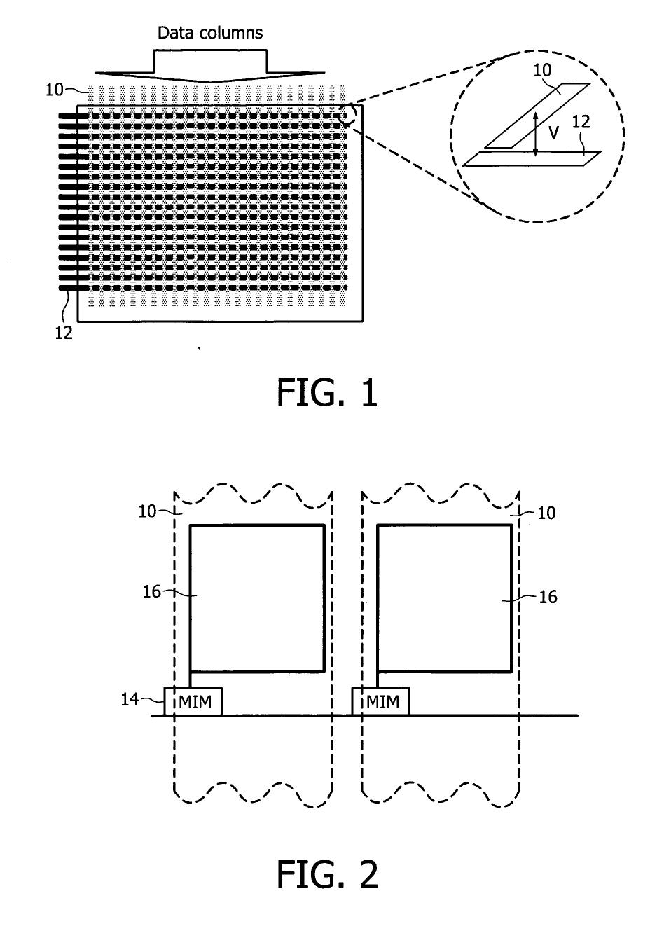

FIG. 2 shows a known use of MIM diodes in an active matrix display device with electric field orientation perpendicular to the substrate;

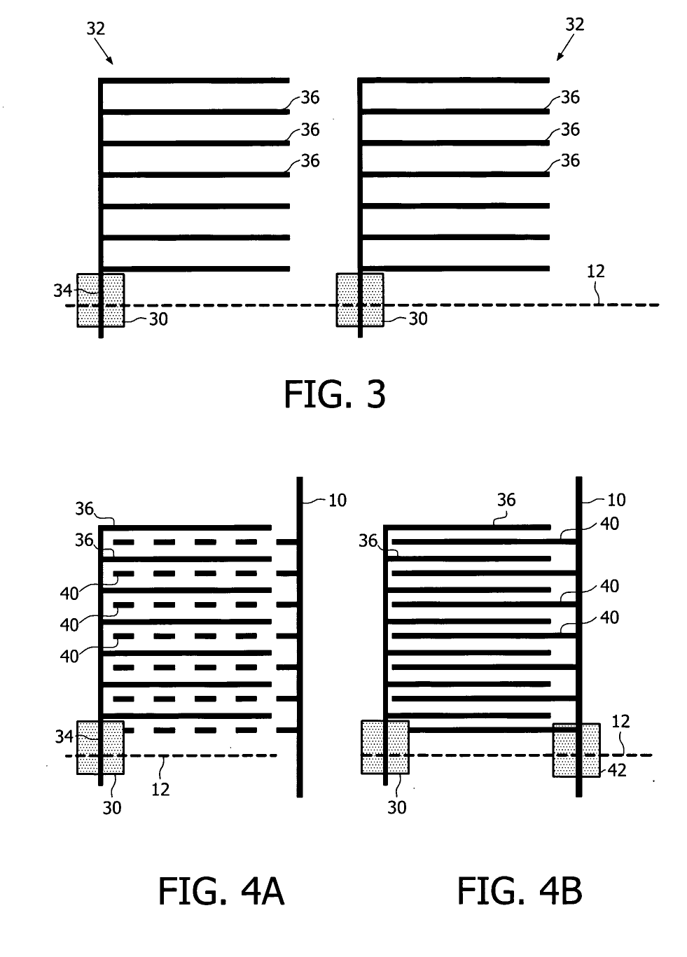

FIG. 3 shows a possible layout of the first substrate of an In-Plane Switching MIM diode based active matrix display device;

FIGS. 4A and 4B show two variations of the full pixel structure for the device of FIG. 3, FIG. 4A shows one possible example and FIG. 4B is in accordance with the invention;

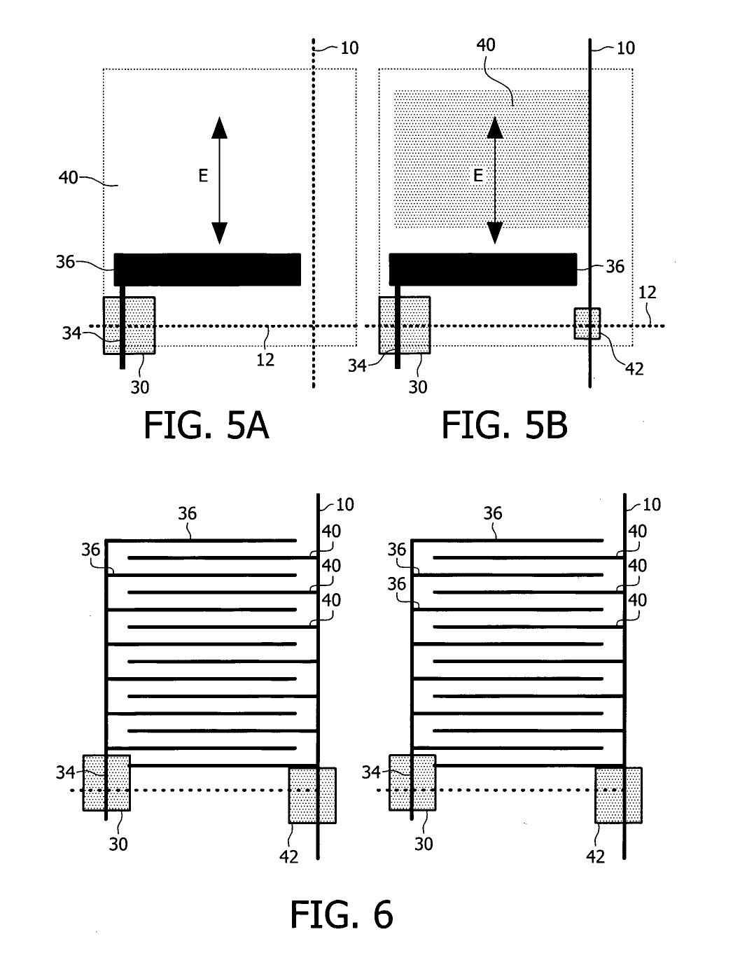

FIGS. 5A and 5B show two variations of the full pixel structure for a second example of device, and FIG. 5A shows one possible example and FIG. 5B is in accordance with the invention;

FIG. 6 shows the full pixel structure for a third example of device of the invention;

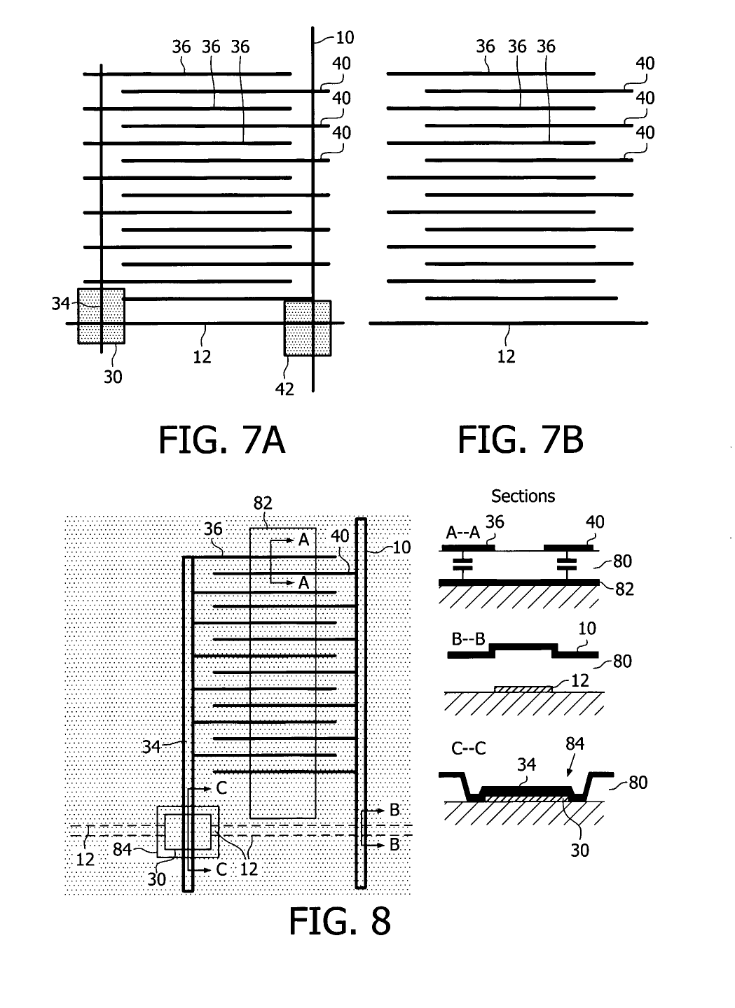

FIGS. 7A and 7B show the full pixel structure for a fourth example of device of the invention;

FIG. 8 shows the full pixel structure for a fifth example of device of the invention in which each pixel has an integrated storage capacitor; and

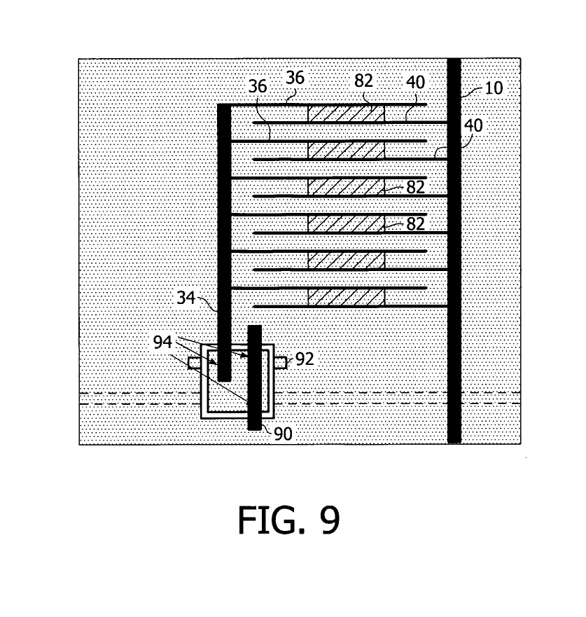

FIG. 9 shows a modification to the example of FIG. 8 to provide multiple series MIM diode for each pixel.

The same references are used in different Figures to denote the same layers or components, and description is not repeated.

FIG. 2 shows a known use of MIM diodes in an active matrix display. The layout is similar to the passive matrix display shown in FIG. 1. However, a MIM diode 14 is introduced as a non-linear resistance element into each pixel, to allow for active matrix addressing. This structure generates electric fields perpendicular to the plane of the display, and as such are unsuitable for an in-plane switching electrophoretic display. The column electrodes 10 are again provided on a top substrate and act as the data lines, and the row electrodes 12 are provided on the bottom substrate, and act as select lines. The MIM diode connects the select line to a pixel electrode pad 16.

In order to create an in-plane electric field, the electrodes within a pixel must be situated adjacent to each other in the plane of the display.

A first possible example of pixel layout is shown FIG. 3.

FIG. 3 shows only the lower substrate, and shows the row conductor 12 extending across all the pixels of a row. In the example of FIG. 3, the row conductor is the bottom layer and is provided over the substrate. An insulator layer has portions 30 disposed over parts of the row conductor. A first electrode pattern 32 includes an end terminal 34 which crosses the row conductor portion with the insulator portion 30 therebetween. The part of the row conductor beneath the insulator portion 30, the insulator portion 30 itself and the end terminal 34 define a Metal-Insulator-Metal diode. The first electrode pattern 32 also defines a first in-plane pixel electrode terminal 36, which in the example of FIG. 3 has a comb pattern.

The MIM device is thus created by separating two metal layers by a thin insulating layer (examples are hydrogenated silicon nitride sandwiched between Cr or Mo metals, or tantalum oxide insulator between Ta metal electrodes), and is conveniently realised in the form of a cross over structure. The cross over structure is a preferred embodiment for a roll-to-roll manufacturing process, as it makes the alignment of the electrodes less critical.

The MIM connects the selection line (the bottom metal row conductor) to the pixel electrode 36 (the top metal layer). Both metal layers and also the insulating layer are realised on the same substrate.

The MIM device effectively functions as back-to-back Schottky diodes. The insulator layer typically is a material having a higher bandgap than conventional semiconductors, although the insulator layer may be formed from a semiconductor material, for example nitrogen-doped amorphous silicon.

The pixel is completed by either providing a second structured electrode on a second substrate, or alternatively by adding an extra electrode layer to the first substrate and separating it with a further (thicker) insulating layer.

FIG. 4A shows the second electrode defined on a separate top substrate as one possible example, and shows the top electrode having a portion of the column conductor 10 which extends across all the pixels of a column, and a second in-plane electrode terminal 40 which is connected to the column conductor 10. The second in-plane electrode terminal 40 is laterally spaced from the first in-plane pixel electrode terminal. In this example, the second in-plane pixel electrode terminal 40 also comprises a comb pattern, which is interleaved with the first in-plane electrode terminal 36.

FIG. 4B shows the second electrode defined on the same substrate in accordance with the invention, again having a portion of the column conductor 10 and the second in-plane electrode terminal 40. A second insulator 42 is provided at the cross over of the row and column conductors 12,10.

FIGS. 5A and 5B show an alternative arrangement, in which the first in-plane pixel electrode terminal 36 comprises an electrode block which extends parallel to the row conductor 12 and the second in-plane pixel electrode terminal 40 comprises an electrode block which is spaced from the first in-plane pixel electrode block terminal 36 in the column direction.

As in FIGS. 4A and 4B, FIG. 5A shows the second electrode defined on a separate top substrate as one possible example, and FIG. 5B shows the second electrode defined on the same substrate in accordance with the invention.

The layouts described above all use three metal layers to realise the active matrix structure. Whilst this is necessary in the case where the second pixel electrode 40 is situated on a second substrate, it is possible to use the same metal layer for both pixel electrodes when both layers are situated on the same substrate.

FIG. 6 is a first example of pixel layout in which the in-pixel electrode patterns are defined by a common metal layer.

In the example of FIG. 6, the first electrode patterns (including the end terminals 34 and the in-plane pixel electrodes 36), the column conductors 10 and the second in-plane electrode terminals 40 are all formed from a common metal layer. This is the first layer disposed over the substrate. The first 30 and second 42 insulator portions are disposed over the common metal layer, and the row conductor 12 is disposed over the first and second insulator portion 30,42.

This saves a mask step, but also has the additional advantage that it avoids certain limitations associated with roll-to-roll manufacturing (or other low cost manufacturing, such as printing based manufacturing methods).

Firstly, it is difficult to accurately align two structured layers relative to each other. For example, in the case of FIG. 4A or 4B, it may be difficult to arrange the in-plane electrode terminal 40 to be positioned precisely between the in-plane electrode terminal 36.

In the embodiment of FIG. 6, the alignment sensitive layers have been structured in the same processing step, as both sets of in-plane electrode terminals are created in the same patterning step.

In the embodiment of FIG. 6, a single complex pattern is used (i.e. a 2-dimensional structured pattern). This pattern is the first structured layer in the process. In this case, all further layers can be patterned in the form of simple one-dimensional lines, or blocks (such as the cross over and MIM insulator, which can be considered as a short line). The row conductor pattern is a simple 1D pattern, which form the MIM device together with the structured in-plane pixel electrodes terminals. A block of insulating material 42 again forms the cross over, whilst a thinner insulating layer 30 forms the MIM diode insulator.

A second limitation is that it is easier to create simple lines than complex patterns. It is preferred to use layouts that are exclusively patterned in any one patterning step in the form of simple one-dimensional lines or blocks. A further embodiment, shown in FIG. 7, addresses this issue.

In FIG. 7, portions of the first in-plane pixel electrode terminals 36, the row conductors 12 and portions of the second in-plane pixel electrode terminals 40 are all formed from a common metal layer. These portions all run parallel to the rows, so that the pattern of the common metal layer, as shown in FIG. 7B, is simply a pattern of horizontal lines.

These horizontal lines form the comb lines of the comb patterns. The comb lines of the first in-plane pixel electrode terminal 36 are connected by the end terminal 34, which is extended to reach to all of the comb lines within the pixel, and the comb lines of the second in-plane pixel electrode terminal 40 are connected by the column conductors 10. The end terminal 34 and the column conductors 10 are formed from a different metal layer. These lines are oriented exclusively in the vertical direction.

The common metal layer is disposed first over the substrate, and the first and second insulator portions 30,42 are disposed over the common metal layer. The column conductors 10 and the (extended) end terminals 34 of the first electrode pattern are disposed over the first and second insulator portions.

In FIG. 7, alignment tolerance is realised by extending the pixel electrodes beyond the switching area of the pixel. In particular, the comb lines are longer than in FIG. 6, so that a cross-over contact is realised between the comb lines and the column conductor 10 and end terminal 34.

This embodiment has an improved roll-to-roll compatible layout with only 1-dimensional patterned structures which for each metal layer are oriented in only a single direction.

The performance of active matrix displays is improved by adding a storage capacitor to the active matrix pixel circuit. However, it has traditionally been difficult to incorporate a storage capacitor into a MIM based active matrix without adding additional processing steps.

The provision of both electrodes which drive the electro-optic effect on the same substrate in some of the examples above enables a design containing a storage capacitor to be realised in a simple way.

FIG. 8 shows an example of MIM based IPS active matrix layouts which incorporates a storage capacitor.

FIG. 8 shows the pixel layout in plan view and also shows three cross sections. The column conductors and the second in-plane electrode terminals are again formed on the substrate, and a second insulator layer 80 is provided between the cross over of the row and column conductors. This insulator layer extends over substantially all of the substrate, and is used to form a capacitor dielectric layer. The insulator layer 80 is continuous but has an opening 84.

The first layer deposited is the layer defining the row conductors 12, and this layer is also used to form a capacitor terminal 82. This material of the row conductors may be transparent, to provide a transparent capacitor terminal.

The insulator portion 30 of the Metal-Insulator-Metal diode is formed in the opening 84, and the common metal layer is formed over the insulator portion 30 of the Metal-Insulator-Metal diode device and over the second insulator layer 80.

Over the insulator layer 80, the first electrode patterns 34,36, the column conductors 10 and the second in-plane electrode terminals 40 are all formed from a common metal layer.

As shown in section A-A, the storage capacitor is formed from the layer of row metal underlying the crossover dielectric, and is formed as two capacitors in series between the two in-plane pixel electrode terminals. The capacitor dielectric is therefore effectively twice the crossover dielectric thickness.

Section B-B shows the insulator layer 80 used for the cross over insulator and section C-C shows the formation of the MIM diode in the opening 84 in the layer 80.

If desired, the capacitance can be increased by making a via from one of the pixel electrode terminals down to the capacitor metal, as this will effectively half the thickness of the dielectric layer (to the thickness of the crossover dielectric).

An issue may be that in the area of the storage capacitor the lateral field will be disturbed by the presence of the capacitor terminal under the inter-electrode space. One way to reduce this effect is to position the capacitor conductor to one side of the pixel.

The only patterning of capacitor/crossover dielectric layer 80 which is required is to make a hole for the MIM to fit in. This patterning does not require very accurate dimensions or alignment, making it compatible with the roll-to-roll process.

The MIM dielectric can in fact be present all over the pixel - it only needs patterning to remove it from contacts around edge of display, and that patterning does not require accurate dimensions or alignment, making it compatible with roll to roll processes. Ageing of the MIM device is approximately proportional to the thickness squared of the insulator layer, for a number of types of MIM device. Consequently, if ageing for a MIM with layer thickness D is k.D², the ageing for 3 layers of thickness D/3 is 3 k.D²/9=kD²/3. This gives a reduction by a factor of 3 compared to a single MIM device. There is therefore a benefit in using a thinner insulator layer, and having a number of devices in series.

An example of such a layout, as a modification to the example of FIG. 8, is shown in FIG. 9. It is noted that the use of multiple MIM diodes in series can be applied to any embodiments of the invention.

The first electrode pattern includes a second isolated end terminal 90, and the material of the row conductor 12 defines an isolated additional terminal 92. The Metal-Insulator-Metal diode device then comprises three diodes 94 in series.

A layout with multiple MIM devices in series is useful for improved lifetime of the MIM device. The voltage range for driving an electrophoretic display is relatively large, so that a layout with three MIM devices in series is particularly useful.

In the layout of FIG. 8, the storage capacitor is formed as a single structure from the first (row) metal layer separated by the crossover dielectric from the pixel electrodes. If for any reason the pixel electrodes are short circuited via the storage capacitor, then the pixel will stop functioning. This may be the result of localised defects in the dielectric layer. If one defect causes one in-plane electrode terminal to be shorted to the capacitor terminal, and another defect causes the other in-plane electrode terminal to be shorted to the capacitor terminal, the pixel will be short-circuited.

FIG. 9 also shows a modification to the capacitor terminal 82, in which the terminal is formed as a number of pads which extend between adjacent comb lines of the two in-plane electrode terminals. These pads extend between and beneath the adjacent pairs of comb lines (although it cannot be seen from FIG. 9 that they extend beneath the terminals 36,40). If there is a localised defect in the dielectric layer, this will result in a short between one pad of the capacitor terminal 82 and one in-plane electrode terminal. However, this short circuit will be localised as the pads of the capacitor terminal 82 are not connected together. In this case, only short circuits in two adjacent parts of the dielectric layer will cause a short circuit between the electrode terminals.

The examples above have the intermediate capacitor terminal formed as the first layer. It is also possible for the capacitor terminal to provided at the top of the structure.

The storage capacitor can be formed using TaOx MIMs. In this process, the Ta layers are oxidised using an anodic oxidation step (i.e. oxidation in a fluid bath under the influence of an applied voltage). In this manner, a specific oxide thickness is realised for creating the MIM device with the required electrical characteristics.

A similar fluid based oxidation process (not necessarily using an applied voltage) can be used in order to either simultaneously or sequentially create a further insulation layer by oxidation of the surface of a different metal layer. An example of a suitable metal could be Al, which is known to form a thin native oxide that is a good insulator and could form the basis of a storage capacitor. Ideally, the insulator should be as thin as possible with a higher bandgap than the TaOx layer. In the sequential situation, Al layers could first be deposited and oxidised (in a first fluid bath), whilst the Ta could be deposited at a later time and then anodically oxidised.

The examples above use two in-plane electrodes to control the movement of particles. It is also possible to introduce additional control terminals. For example, a third control terminal can be provided between the two other terminals and can be used to halt the movement of particles, once a desired grey level has been achieved. Alternatively, an additional control terminal can be used to accelerate the movement of particles so that addressing can be achieved more rapidly. There may, for example, be a high voltage control terminal and a low voltage control terminal.

With reference to FIG. 5B, an additional control terminal may be provided between the terminals 36 and 40, and can be used to halt the movement of particles between the terminals 36 and 40.

The additional control terminals may also be situated on a second substrate, situated opposite to the first substrate. In this case, the use of additional control terminals can also enable a hybrid system to be developed which combines in-plane switching with orthogonal switching. The particles can then be moved to locations adjacent the in-plane electrodes at one vertical position within the material layer, or to locations randomly dispersed and at another vertical position within the material layer.

The additional, third, electrode may be connected to an associated row or column conductor by a further associated MIM device.

In all of the examples above, the MIM device (or devices) is provided between the select line and one of the pixel electrodes. This defines a pixel circuit comprising the select line, then the MIM device, then the display material layer, and then the column data electrode in series. The MIM device may instead be defined between the pixel electrode and the column data electrode, without altering the electrical operation of the pixel circuit. Thus, the invention is intended to cover this possibility.

In all of the examples above, the select or scanning electrode (which defines the pixels being addressed at any time) is considered to be the row electrode, whilst the data electrodes (which provide the information to the pixel) are considered to be the column electrodes. In alternative arrangements, the select and data electrodes could be chosen to be differently oriented, for example in the column and row directions respectively, or even in a honeycomb arrangement without altering the electrical operation of the pixel circuit. Thus, the invention is intended to cover this possibility.

The examples above relate to an electrophoretic display device. The invention can be used in other in-plane switching devices using MIM devices for active matrix addressing, for example IPS LC displays.

The mere fact that certain measures are mentioned in different claims below does not indicate that a combination of these measures cannot be used to advantage.

Electrophoretic display systems can form the basis of a variety of applications where information may be displayed, for example in the form of information signs, public transport signs, advertising posters, pricing labels, billboards etc. In addition, they may be used where a changing non-information surface is required, such as wallpaper with a changing pattern or colour, especially if the surface requires a paper like appearance.

Various modifications will be apparent to those skilled in the art.

1. An active matrix device, comprising an array of rows and columns of pixels disposed over a substrate, each pixel comprising, over a common substrate:
a portion of a row conductor (12), the row conductor extending past all the pixels of a row;
a first electrode pattern (32) including a first in-plane electrode terminal (36), associated with the row conductor portion (12),
a portion of a column conductor (10), the column conductor extending past all the pixels of a column;
a second electrode pattern including a second in-plane electrode terminal (40), associated with the column conductor portion (10);
a first insulator portion (30) disposed between the row conductor portion (12) and the first electrode pattern (32) or between the column conductor portion (10) and the second electrode pattern (40), the insulator portion (30) and the surrounding electrode pattern (32 or 40) and conductor portion (12 or 10) defining a Metal-Insulator-Metal diode device.

2. A device as claimed in claim 1, wherein the first electrode pattern (32) includes a portion (34) which crosses the row conductor portion (12), the first insulator portion (30) being provided between the portion (34) of the first electrode pattern and the row conductor portion (12).

3. A device as claimed in claim 2, wherein each pixel further comprises a second insulator portion (42) between the overlap of the row conductor portion (12) and the column conductor portion (10).

4. A device as claimed in claim 1, wherein the first in-plane pixel electrode terminal (36) comprises a comb pattern.

5. A device as claimed in claim 4, wherein the second in-plane pixel electrode terminal (40) comprises a comb pattern.

6. A device as claimed in claim 1, wherein the first in-plane electrode terminals (36) and the second in-plane electrode terminals (40) are formed from the same metal layer.

7. A device as claimed in claim 1, wherein the column conductor portions (10) and the second in-plane electrode terminals (40) are formed from the same metal layer.

8. A device as claimed in claim 7, wherein the common metal layer is disposed over the substrate, the first insulator portion (30) is disposed over at least a part of the common metal layer and the row conductor (12) is disposed over the first insulator portion (30).

9. A device as claimed in claim 1, wherein the first in-plane pixel electrode terminals (36), the row conductors (12) and the second in-plane pixel electrode terminals (40) are all formed from a common metal layer.

10. A device as claimed in claim 9, wherein the first in-plane electrode terminals (36) comprise substantially parallel comb lines, and wherein the first electrode pattern further comprises a substantially perpendicular connecting portion (34) connecting the parallel comb lines.

11. A device as claimed in claim 10, wherein the second in-plane electrode terminal (40) comprises comb lines substantially parallel to the comb lines of the first in-plane electrode terminal, and wherein the column conductor portions (10) connect the parallel comb lines of the second in-plane electrode terminal (40).

12. A device as claimed in claim 11, wherein the common metal layer is disposed over the substrate, the first insulator portion (30) is disposed over at least a portion of the common metal layer, and the connecting portions (34) are disposed over the first insulator portions.

13. A device as claimed in claim 12, wherein the column conductors (10) are disposed over the first insulator portions (30).

14. A device as claimed in claim 13, wherein the column conductors (10) and the connecting portions (34) cross over the respective comb lines, the comb lines thereby extending beyond the location of the column conductors and the connecting portions.

15. A device as claimed in claim 9, wherein the common metal layer is formed from an array of substantially parallel lines.

16. A device as claimed in claim 15, wherein the column conductors (10) and the connecting portions (34) are formed from a further metal layer comprising an array of parallel lines.

17. A device as claimed in claim 16, wherein the lines of the further metal layer are substantially perpendicular to the parallel lines of the common metal layer.

18. A device as claimed in claim 1, wherein all conductors in any single layer of the layer or layers forming the row conductors (12), the first electrode patterns (32), the column conductors (10) and the second electrode patterns (40), are formed from substantially parallel lines.

19. A device as claimed in claim 1, wherein the first in-plane electrode terminals (36) and the second in-plane electrode terminals (40) are formed from the same layer, and wherein each pixel further comprises a capacitor terminal (82).

20. A device as claimed in claim 19, wherein the capacitor terminal (82) of each pixel provides a capacitive coupling between the first and second in-plane electrode terminals (36,40).

21. A device as claimed in claim 19, wherein the row conductors (12) are disposed over the substrate, wherein the first in-plane pixel electrode terminals (36), the column conductors (10) and the second in-plane pixel electrode terminals (40) are all formed from a common metal layer, and wherein the row conductor layer further defines an array of capacitor terminals (82), with a capacitor terminal for each pixel.

22. A device as claimed in claim 19, wherein each pixel further comprises a second insulator portion (80) between the overlap of the row conductor portion (12) and the column conductor portion (10), and wherein the second insulator portion (80) extends over the row conductors (12) and over the capacitor terminals, and wherein the common metal layer is formed over the second insulator portion (80).

23. A device as claimed in claim 22, wherein the one of the in-pixel electrode terminals (36,40) makes contact with the capacitor terminal.

24. A device as claimed in claim 22, wherein the second insulator portion (80) is substantially continuous and is provided with an opening (84) in which the first insulator portion (30) of the Metal-Insulator-Metal diode is formed, the common metal layer being formed over the insulator portion (30) of the Metal-Insulator-Metal diode device and the second insulator portion (80).

25. A device as claimed in claim 24, wherein the first insulator portion of the Metal-Insulator-Metal diode device comprises a first oxidized layer of the metal layer forming one terminal of the Metal-Insulator-Metal diode device.

26. A device as claimed in claim 25, wherein the second insulator portion (80) over the capacitor terminal comprises a second oxidized layer of the metal layer forming the capacitor terminal.

27. A device as claimed in claim 26, wherein the first and second oxidized layers have different thickness.

28. A device as claimed in claim 1, comprising an electrophoretic active matrix device and/or a display device.

29. A method of manufacturing an active matrix device, comprising an array of rows and columns of pixels disposed over a substrate, the method comprising forming, over a common substrate:
a row conductor (12) array;
an array of first electrode patterns (32) each including a first in-plane electrode terminal (36);
a column conductor (10) array;
an array of second electrode patterns each including a second in-plane electrode terminal (40), wherein the method comprises forming a first insulator layer having portions (30) between the row conductor (12) array and the first electrode pattern (32) array or between the column conductor (10) array and the second electrode pattern (40) array, the insulator portions (30) and the surrounding electrode pattern (32 or 40) and conductor portion (12 or 10) defining a Metal-Insulator-Metal diode device.
